(19) United States
(12) Patent Application Publication
(10) Pub. No.: US 2025/0052823 A1
(43) Pub. Date: Feb. 13, 2025

(54) BATTERY ABNORMALITY DETECTION SYSTEM, BATTERY ABNORMALITY DETECTION METHOD, AND NON-TRANSITORY COMPUTER-READABLE RECORDING MEDIUM

(71) Applicant: Panasonic Intellectual Property Management Co., Ltd., Osaka (JP)

(72) Inventors: Takashi MATSUDA, Osaka (JP); Yusuke ITAKURA, Nara (JP); Shinya NISHIKAWA, Osaka (JP); Masaaki TAKEGATA, Osaka (JP); Hiroshi TAKAO, Osaka (JP); Takashi IIDA, Hyogo (JP)

(21) Appl. No.: 18/721,151

(22) PCT Filed: Dec. 7, 2022
(86) PCT No.: PCT/JP2022/045070

§ 371 Date: Jun. 17, 2024

(30) Foreign Application Priority Data
Dec. 24, 2021 (JP) 2021-210649

(51) Int. Cl. G01R 31/374; G01R 31/367; G01R 31/3828; G01R 31/3842; G01R 31/396; H01M 10/48

(52) U.S. Cl. CPC G01R 31/374; G01R 31/367; G01R 31/3828; G01R 31/3842; G01R 31/396; H01M 10/486

(57) ABSTRACT

In a battery abnormality detection system, a data acquirer acquires a current flowing through a battery and a temperature of the battery. A determiner determines presence or absence of abnormal heat generation of the battery based on a relation between an amount of the current flowing through the battery in a certain period and a temperature rise of the battery in the certain period. The determiner determines the presence or absence of the abnormal heat generation of the battery based on the current and the temperature of the battery in a charging period in which the temperature of the battery exceeds a set temperature.

### CROSS-REFERENCE TO RELATED APPLICATIONS

This application is based upon and claims the benefit of priority from the prior Japanese Patent Application No. 2021-210649, filed on Dec. 24, 2021, and the International Patent Application No. PCT/JP2022/045070, filed on Dec. 7, 2022, the entire content of each of which is incorporated herein by reference.

### BACKGROUND

### Field of the Invention

The present disclosure relates to a battery abnormality detection system, a battery abnormality detection method, and a battery abnormality detection program for detecting abnormal heat generation of a battery.

### Description of the Related Art

A battery pack is mounted on devices such as an electric vehicle, a notebook PC, and a smartphone. A temperature sensor is attached to a surface of a cell in the battery pack. A temperature measured by the temperature sensor is also affected by a temperature around the battery. In particular, when there is a heat generating electronic component such as a power supply circuit around the battery, the temperature is greatly affected by the electronic component. In addition, in the PC and the smartphone, the temperature is also affected by an installation environment and a use environment.

As a method for detecting abnormal heat generation of a cell in a battery pack, a method for detecting abnormal heat generation of the cell based on a temperature change of a heat absorption member containing a phase change material that changes in phase depending on a use condition of the battery pack has been proposed (see, for example, Patent Literature 1). By using a property that an endothermic amount increases in a predetermined temperature range of the phase change material and setting the temperature range to a range higher than an environmental temperature and lower than an allowable maximum temperature of the cell, an influence of the environmental temperature can be removed.

Patent Literature 1: JP 2020-145060

However, in the above method, it is necessary to separately provide the heat absorption member containing the phase change material in the battery pack, and the cost increases. In addition, the above method cannot be used in an existing general battery pack. In addition, it is conceivable to separately install a temperature sensor for measuring the environmental temperature outside the battery pack, but in this case, the cost also increases.

### SUMMARY OF THE INVENTION

The present disclosure has been made in view of such a situation, and an object thereof is to provide technology for detecting abnormal heat generation of a battery while suppressing an influence of an environmental temperature.

In order to solve the above problem, a battery abnormality detection system according to one aspect of the present disclosure includes: an acquirer that acquires a current flowing through a battery and a temperature of the battery; and a determiner that determines presence or absence of abnormal heat generation of the battery based on a relation between an amount of the current flowing through the battery in a certain period and a temperature rise of the battery in the certain period. The determiner determines the presence or absence of the abnormal heat generation of the battery based on the current and the temperature of the battery in a charging period in which the temperature of the battery exceeds a set temperature.

Note that arbitrary combinations of the above components and conversions of an expression of the present disclosure between a device, a system, a method, a computer program, and the like are also effective as aspects of the present disclosure.

Embodiments will now be described, by way of example only, with reference to the accompanying drawings which are meant to be exemplary, not limiting, and wherein like elements are numbered alike in several Figures, in which:

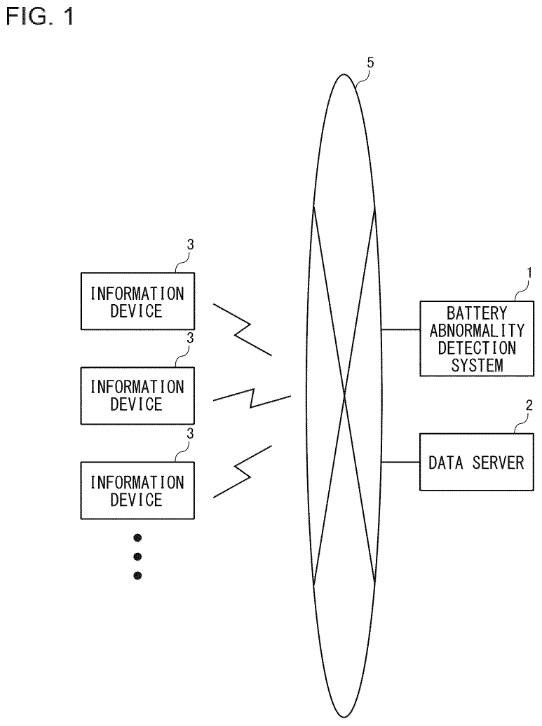

FIG. 1 is a diagram illustrating a battery abnormality detection system according to an embodiment.

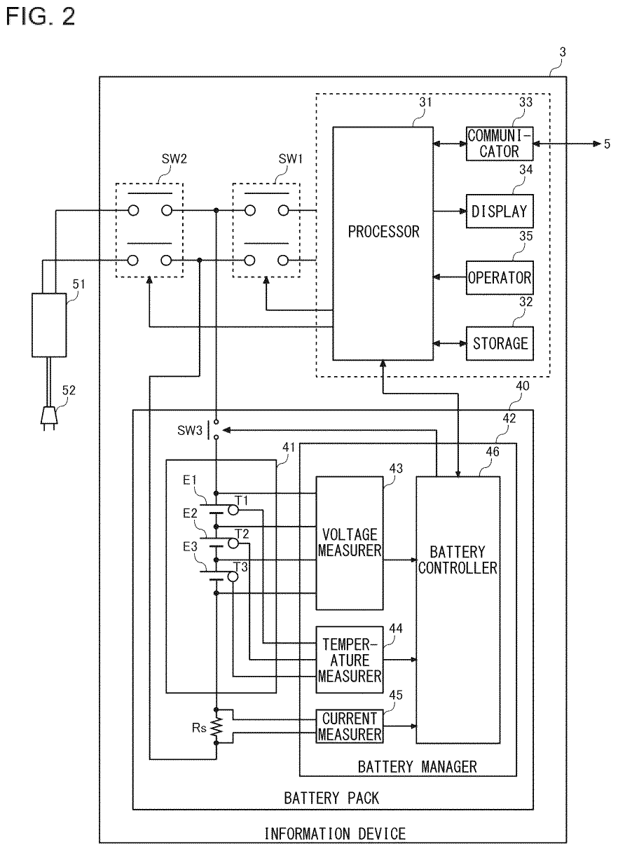

FIG. 2 is a diagram illustrating a configuration example of an information device.

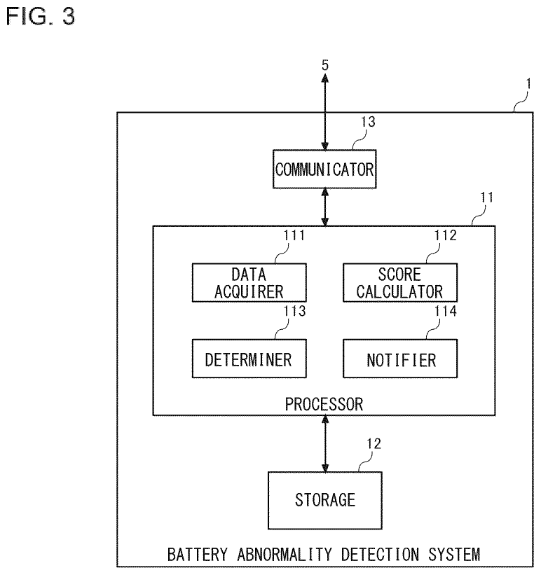

FIG. 3 is a diagram illustrating a configuration example of the battery abnormality detection system according to the embodiment.

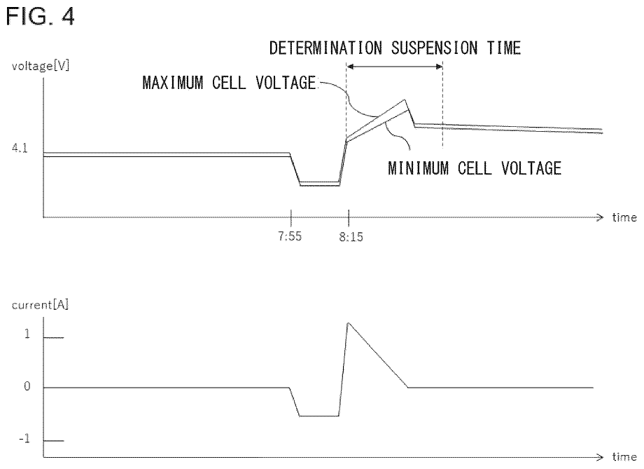

FIG. 4 is a diagram illustrating time-series data of a maximum cell voltage, a minimum cell voltage, and a current of a battery module.

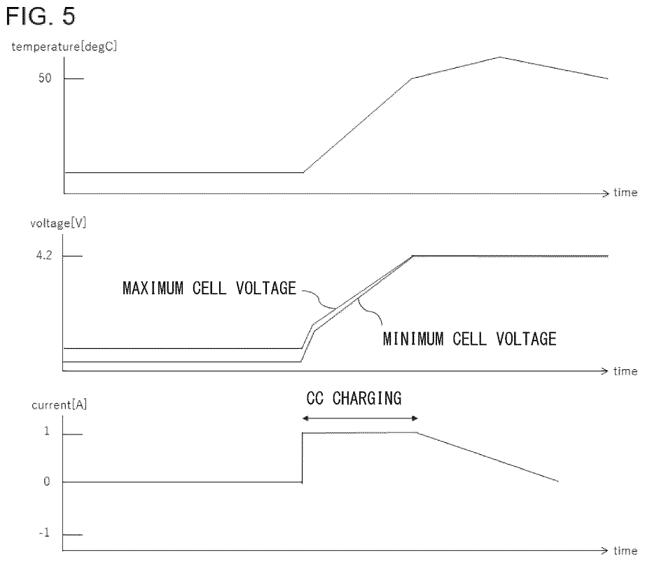

FIG. 5 is a diagram illustrating time-series data of a temperature, a maximum cell voltage, a minimum cell voltage, and a current of another battery module.

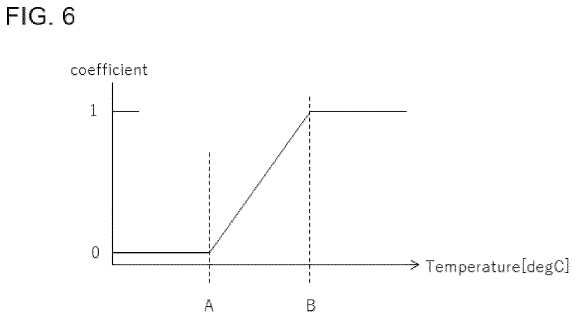

FIG. 6 is a diagram illustrating an example of an adjustment ratio of a heat generation coefficient.

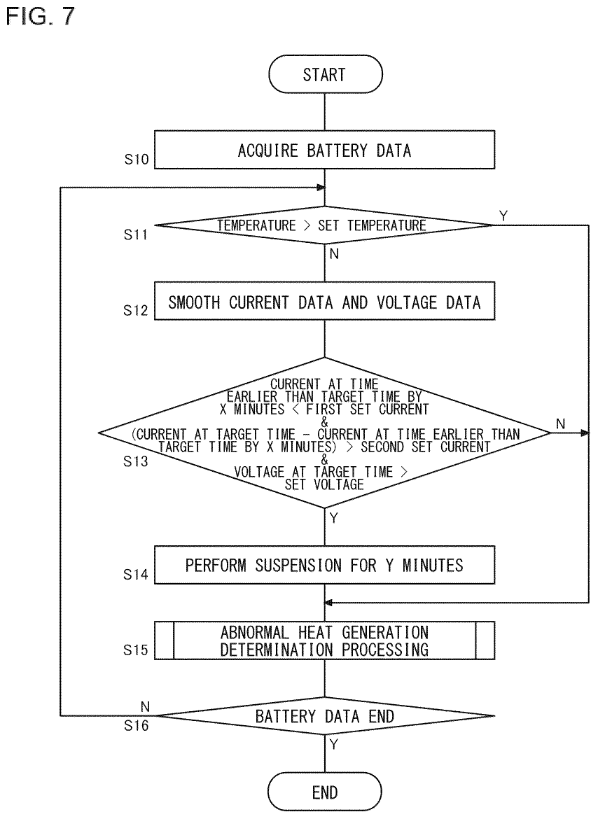

FIG. 7 is a flowchart illustrating a flow of battery abnormality detection processing according to the embodiment.

### DETAILED DESCRIPTION OF THE INVENTION

The invention will now be described by reference to the preferred embodiments. This does not intend to limit the scope of the present invention, but to exemplify the invention.

FIG. 1 is a diagram illustrating a battery abnormality detection system 1 according to an embodiment. The battery abnormality detection system 1 according to the embodiment is a system used by an individual or a corporation who uses an information device 3. In the present embodiment, a notebook PC is assumed as the information device 3, and an example in which a corporation that lends a plurality of notebook PCs to employees uses the battery abnormality detection system 1 is assumed.

For example, the battery abnormality detection system 1 may be constructed on an own server installed in an own facility or a data center of a provider providing a battery analysis service. In addition, the battery abnormality detection system 1 may be constructed on a cloud server used based on a cloud service. In addition, the battery abnormality detection system 1 may be constructed on a plurality of servers dispersedly installed in a plurality of bases (data centers and own facilities). The plurality of servers may be a combination of a plurality of own servers, a combination of a plurality of cloud servers, or a combination of own servers and cloud servers.

The information device 3 has a communication function and can be connected to a network 5. The information device 3 transmits battery data of a mounted battery pack 40 to a data server 2 via the network 5. The information device 3 samples the battery data of the battery pack 40 periodically (for example, one minute interval), accumulates the battery data in an internal storage 32 (see FIG. 2), and collectively transmits the battery data accumulated in the storage 32 to the data server 2 at predetermined timing (for example, timing set at a frequency of once a week).

The data server 2 acquires and accumulates the battery data from the information device 3. The data server 2 may be an own server installed in an own facility or a data center of a battery analysis service provider or a provider using a plurality of information devices 3, or may be a cloud server used by the battery analysis service provider or the provider using the plurality of information devices 3. In addition, each of them may have the data server 2.

The network 5 is a general term for communication paths such as the Internet, a dedicated line, and a virtual private network (VPN), and a communication medium and a protocol thereof are not limited. As the communication medium, for example, a mobile phone network (cellular network), a wireless LAN, a wired LAN, an optical fiber network, an ADSL network, a CATV network, or the like can be used. As the communication protocol, for example, a transmission control protocol (TCP)/Internet protocol (IP), a user datagram protocol (UDP)/IP, Ethernet (registered trademark), or the like can be used.

FIG. 2 is a diagram illustrating a configuration example of the information device 3. The information device 3 includes a processor 31, a storage 32, a communicator 33, a display 34, a battery pack 40, a first switch SW1, and a second switch SW2. The processor 11 integrally controls the entire information device 3. Functions of the processor 31 can be implemented by cooperation of hardware resources and software resources or only hardware resources. As the hardware resources, a CPU, a ROM, a RAM, a graphics processing unit (GPU), an application specific integrated circuit (ASIC), a field programmable gate array (FPGA), and other LSIs can be used. Programs such as an operating system and an application can be used as the software resources.

The storage 32 includes a nonvolatile recording medium such as an HDD or an SSD, and stores various data. In the present embodiment, the battery data supplied from the battery pack 40 is stored. The communicator 33 is a communication interface (for example, a network interface card (NIC)) for connecting to the network 5 in a wired or wireless manner.

The display 34 includes a liquid crystal display, an organic EL display, a mini LED display, and the like, and displays a video signal supplied from the processor 31. The operator 35 includes a mouse and a keyboard, receives a user's operation, and outputs an operation signal based on the operation content to the processor 31. Note that a touch panel display in which the functions of the display 34 and the operator 35 are integrated may be used. In this case, a user can perform a touch operation on the display.

A main body of the information device 3 including the processor 31, the storage 32, the communicator 33, and the display 34 receives power supplied from at least one of the commercial power system or the battery pack 40. The main body of the information device 3 is connected to the DC side of an AC adapter 51 via the first switch SW1 and the second switch SW2. When an AC plug 52 connected to the AC side of the AC adapter 51 is inserted into an AC outlet, an AC voltage is input from the commercial power system to the AC adapter 51.

The AC adapter 51 includes an AC/DC converter, and the AC/DC converter converts an input AC voltage into a predetermined DC voltage. For example, the AC/DC converter converts an input AC voltage of 100/200 V into a DC voltage of about 14 to 20 V.

The battery pack 40 is a detachable battery pack, and includes a battery module 41, a battery manager 42, and a third switch SW3. The third switch SW3 may be connected to the positive electrode side or the negative electrode side of the battery module 41. A relay or a semiconductor switch can be used as the first switch SWI to the third switch SW3.

The main body of the information device 3 can receive the supply of the DC voltage from the AC adapter 51 via the first switch SW1 and the second switch SW2. The battery module 41 can charge the DC voltage supplied from the AC adapter 51 via the first switch SW1 and the third switch SW3. The main body of the information device 3 can receive the supply of the DC voltage discharged from the battery module 41 via the first switch SW1 and the third switch SW3.

The battery module 41 includes a plurality of cells E1 to E3 (the number of series of three is assumed in the present embodiment). FIG. 2 illustrates a configuration example in which the plurality of cells E1 to E3 are connected in series. Note that a plurality of parallel cell blocks configured by connecting a plurality of cells in parallel may be connected in series. For example, the battery module 41 with the number of parallels of two and the number of series of three may be used.

As the cell, a lithium ion battery cell, a nickel hydrogen battery cell, a lead battery cell, or the like can be used. Hereinafter, an example using the lithium ion battery cell (nominal voltage: 3.6 to 3.7 V) is assumed in the present specification. The number of series of the cells E1 to E3 or the parallel cell blocks is determined according to the operating voltage of the information device 3.

A shunt resistor Rs is connected in series with the plurality of cells E1 to E3 or the plurality of parallel cell blocks. The shunt resistor Rs functions as a current detection element. Note that a Hall element may be used instead of the shunt resistor Rs. A plurality of temperature sensors T1 to T3 for detecting temperatures of the plurality of cells E1 to E3 or the plurality of parallel cell blocks are installed on surfaces of the cells. Note that the number of temperature sensors may be equal to or smaller than the number of cells. For example, a thermistor can be used as the temperature sensors T1 to T3.

The battery manager 42 includes a voltage measurer 43, a temperature measurer 44, a current measurer 45, and a battery controller 46. Nodes of the plurality of cells E1 to E3 or the plurality of parallel cell blocks connected in series and the voltage measurer 43 are connected by a plurality of voltage lines. The voltage measurer 43 measures voltages between two adjacent voltage lines to measure voltages of the cells E1 to E3 or the parallel cell blocks. The voltage measurer 43 outputs the measured voltages of the cells E1 to E3 or the parallel cell blocks to the battery controller 46.

The voltage measurer 43 includes a multiplexer and an A/D converter. The multiplexer outputs voltages between two adjacent voltage lines to the A/D converter in order from the top. The A/D converter sequentially converts the analog voltage input from the multiplexer into a digital value and outputs the digital value to the battery controller 46.

The temperature measurer 44 includes a voltage division resistor and an A/D converter. The A/D converter sequentially converts a plurality of analog voltages divided by the plurality of temperature sensors T1 to T3 and the plurality of voltage division resistors into digital values and outputs the digital values to the battery controller 46. The battery controller 46 measures temperatures at a plurality of observation points in the battery module 41.

The current measurer 45 includes a differential amplifier and an A/D converter. The differential amplifier amplifies a voltage across the shunt resistor Rs and outputs the amplified voltage to the A/D converter. The A/D converter converts an analog voltage input from the differential amplifier into a digital value and outputs the digital value to the battery controller 46. The battery controller 46 measures the current flowing through the plurality of cells E1 to E3 or the plurality of parallel cell blocks based on the digital value.

Note that, in a case where an A/D converter is mounted in the battery controller 46 and an analog input port is installed in the battery controller 46, the voltage measurer 43, the temperature measurer 44, and the current measurer 45 may output an analog voltage to the battery controller 46, and the analog voltage may be converted into a digital value by the A/D converter in the battery controller 46.

The battery controller 46 manages the states of the plurality of cells E1 to E3 or the plurality of parallel cell blocks based on the voltages, temperatures, and currents of the plurality of cells E1 to E3 or the plurality of parallel cell blocks measured by the voltage measurer 43, the temperature measurer 44, and the current measurer 45. When an overvoltage, an undervoltage, an overcurrent, or a temperature abnormality occurs in at least one of the plurality of cells E1 to E3 or the plurality of parallel cell blocks, the battery controller 46 turns off the third switch SW3 to protect the cell or the parallel cell block.

The battery controller 46 can include a microcontroller and a nonvolatile memory (for example, an electrically erasable programmable read-only memory (EEPROM) and a flash memory). The battery controller 46 estimates an SOC of each of the plurality of cells E1 to E3 or the plurality of parallel cell blocks.

The battery controller 46 estimates the SOC by a combination of an open circuit voltage (OCV) method and a current integration method. The OCV method is a method for estimating the SOC based on an OCV of each cell or each parallel cell block measured by the voltage measurer 43 and an SOC-OCV curve of the cell. The SOC-OCV curve of the cell is created in advance based on a characteristic test by a battery manufacturer, and is registered in an internal memory of the microcontroller at the time of shipment.

The current integration method is a method for estimating the SOC based on the OCV at the start of charging/discharging of each cell or each parallel cell block and the integrated value of the current measured by the current measurer 45. In the current integration method, a measurement error of the current measurer 45 is accumulated as a charging/discharging time becomes longer. On the other hand, the OCV method is affected by a measurement error of the voltage measurer 43 and an error due to a polarization voltage. Therefore, it is preferable to use a weighted average of the SOC estimated by the current integration method and the SOC estimated by the OCV method.

The battery controller 46 periodically (for example, one minute interval) samples the battery data including the voltage, the current, the temperature, and the SOC of each of the cells E1 to E3 or each of the parallel cell blocks, and transmits the battery data to the processor 31. The processor 31 accumulates the received battery data in the storage 32. The processor 31 transmits the battery data accumulated in the storage 32 in batches to the data server 2 at predetermined timing (for example, timing set at a frequency of once a week.).

FIG. 3 is a diagram illustrating a configuration example of the battery abnormality detection system 1 according to the embodiment. The battery abnormality detection system 1 includes a processor 11, a storage 12, and a communicator 13. The communicator 13 is a communication interface (for example, an NIC) for connecting to the network 5 in a wired or wireless manner.

The processor 11 includes a data acquirer 111, a score calculator 112, a determiner 113, and a notifier 114. Functions of the processor 11 can be implemented by cooperation of hardware resources and software resources or only hardware resources. As the hardware resources, a CPU, a ROM, a RAM, a GPU, an ASIC, an FPGA, and other LSIs can be used. Programs such as an operating system and an application can be used as the software resources. The storage 12 includes a nonvolatile recording medium such as an HDD or an SSD, and stores various data.

The data acquirer 111 acquires the battery data of the battery pack 40 to be analyzed from the data server 2. The battery data is time-series data including voltage data of each of the cells E1 to E3 or each of the parallel cell blocks, current data flowing through the battery module 41, and temperature data of the battery module 41. When the plurality of temperature sensors T1 to T3 are installed in the battery module 41, for example, the maximum measured temperature, the average temperature of the maximum measured temperature and the minimum measured temperature, or the average temperature of the temperatures measured by all the temperature sensors T1 to T3 is used as the temperature data of the battery module 41.

At the time of charging the battery module 41, the score calculator 112 calculates a determination score for detecting the abnormal heat generation based on the current, the temperature, and the elapsed time of the battery module 41. The determination score is calculated based on the thermal energy theory. The abnormal heat generation is an event indicating a sign of ignition of the battery pack 40.

The self-calorific value by the charging current is defined by Q (I, R, T).

Q: calorific value [J], I: current [A], R: internal resistance [Ω], T: elapsed time [s] The self-calorific value Q by the charging current increases as the current I increases, the internal resistance R increases, or the elapsed time T increases.

Note that the internal resistance R of the battery depends on an SOC, a temperature, and a state of health (SOH). The internal resistance R increases as the SOC increases, the temperature decreases, or the SOH decreases.

The calorific value of the battery is defined by Q (m, c, ΔTp).

Q: calorific value [J], m: mass of battery [g], c: specific heat of entire battery [J/(g. K)], ATp: temperature rising in T period [° C.]

m and c can be collectively considered as a heat capacity C: [J/K].

The calorific value Q of the battery increases as the heat capacity C increases or the temperature ΔTp increasing at the elapsed time T increases.

If the self-calorific value Q by the charging current falls within the calorific value Q of the battery or less, thermal runaway by self-heating can be prevented. However, the battery data acquired by the data acquirer 111 basically does not include the material, mass, and internal resistance of the cells constituting the battery module 41.

The score calculator 112 derives in advance a determination score indicating a relation between the amount of current flowing through the battery module 41 in a certain period and the temperature rise of the battery module 41 in the certain period. A designer derives the determination score from the current I, the temperature Tp, and the elapsed time T without using the internal resistance and the heat capacity of the cell or the parallel cell block. For example, the determination score may be defined by a ratio between the current integration amount and the temperature rise in the certain period. In a case where the temperature rise is large for the charging current, the determination score (R/C) becomes high when the current integration amount is used as a reference, and the determination score (C/R) becomes low when the temperature rise is used as a reference.

The determiner 113 compares the determination score calculated by the score calculator 112 with a threshold to determine the presence or absence of abnormal heat generation in the battery module 41. The threshold may be determined based on, for example, data of the ignited battery module 41. Specifically, the designer determines the threshold based on the transition data of the determination score of at least one ignited battery module 41. When the transition data of the determination scores of the plurality of ignited battery modules 41 is collected, the transition data of the plurality of determination scores is combined to generate standard data, and the threshold is determined based on the standard data.

The threshold is set to a value at a time point temporally before a value at a time point of ignition of the determination score. When the determination score (R/C) based on the current integration amount is used, the threshold is set to a value lower by a predetermined margin than the determination score at the time point of ignition. On the contrary, when the determination score (C/R) based on the temperature rise is used, the threshold is set to a value higher by a predetermined margin than the determination score at the time point of ignition. In the determination score, the temperature rise by an external factor such as heat generation of the CPU or the power supply circuit other than the temperature rise by self-heating of the cell is also reflected.

In the present embodiment, basically, the current data and the temperature data in the charging period of the battery module 41 are used. In general, the battery module 41 is charged by a constant current, constant voltage (CCCV) method. The CCCV method is a method in which charging is performed with a constant current before the voltage of the battery module 41 reaches a set voltage, and charging is performed with a constant voltage after the voltage reaches the set voltage. The converter in the AC adapter 51 or the battery pack 40 performs control such that the charging current value maintains a current target value during the constant current charging of the battery module 41, and performs control such that the charging voltage value maintains a voltage target value during the constant voltage charging of the battery module 41.

The temperature in the CV charging period after the temperature rises in the CC charging period is stable. In the present embodiment, detection of abnormal heat generation which is hardly affected by the environment is realized by detecting a period in which the temperature rises although the current decreases in the CV charging period.

In addition, in a case where charging is started in a state where the SOC of the battery module 41 is close to full charging, the CC charging may be skipped and the charging may be started from the CV charging. For a section in which the charging is suddenly started by the CV charging, the start timing of the CV period is detected, and a filter is applied so as not to determine abnormal heat generation for a certain period from the start timing.

FIG. 4 is a diagram illustrating time-series data of a maximum cell voltage, a minimum cell voltage, and a current of the battery module 41. In FIG. 4, a positive current is a charging current, and a negative current is a discharging current. In FIG. 4, the information device 3 is used from about 7:55, and the charging current flows from the battery module 41. Charging of the battery module 41 is started from about 8:15. In the battery module 41, a set voltage for switching from the CC charging to the CV charging is set to 4.00 V or less in terms of one cell or one parallel cell block, and this is a case where the charging is suddenly started from the CV charging without undergoing the CC charging. In this case, battery data for a certain period (for example, 50 minutes) from the start of charging is not used. That is, the determination of abnormal heat generation is suspended for a certain period from the start of charging.

FIG. 5 is a diagram illustrating time-series data of a temperature, a maximum cell voltage, a minimum cell voltage, and a current of another battery module 41. FIG. 5 illustrates that the voltage and the temperature are stable during the CC charging, and the voltage and the temperature greatly increase after the start of CV charging.

In the present embodiment, the determination of abnormal heat generation is started from timing when the temperature rise of the cells in the battery module 41 is settled. That is, the determiner 113 determines the presence or absence of abnormal heat generation of the battery module 41 based on the current data and the temperature data in the charging period in which the temperature data of the battery module 41 exceeds the set temperature.

FIG. 6 is a diagram illustrating an example of an adjustment ratio of a heat generation coefficient. The heat generation coefficient is a coefficient by which the determination score (R/C) is multiplied. The adjustment ratio at A° C. or less is 0, and the heat generation coefficient and the determination score (R/C) are also 0. In this case, the determiner 113 does not determine that abnormal heat generation occurs. The adjustment ratio of B° C. or more is 1, the heat generation coefficient is a preset constant, and a value corrected by the heat generation coefficient (constant) is used for the determination score (R/C). Between A° C. and B° C., (0 <adjustment ratio <1) is satisfied, the heat generation coefficient is corrected by multiplying the adjustment ratio, and a value corrected with the corrected heat generation coefficient is used for the determination score (R/C).

When the determiner 113 detects the abnormal heat generation of the battery module 41, the notifier 114 notifies the information device 3 mounted with the battery pack 40 including the battery module 41 of an alert via the network 5. For example, a message such as “Please replace a battery pack.” is added to the alert. When the abnormal heat generation is detected in the battery module 41 included in the battery pack 40 mounted on the corporate information device 3, the notifier 114 also notifies a system administrator of the corporation of an alert.

FIG. 7 is a flowchart illustrating a flow of battery abnormality detection processing according to the embodiment. The data acquirer 111 acquires the battery data of the battery pack 40 mounted on the information device 3 to be analyzed from the data server 2 (S10). When the temperature data included in the battery data during the charging period exceeds the set temperature (for example, A° C.) (Y in S11), the determiner 113 executes determination processing of the abnormal heat generation (S15).

When the temperature data is the set temperature or less (N in S11), the score calculator 112 smooths the current data and the voltage data included in the battery data (S12). For example, the score calculator 112 divides the current data and the voltage data for every n (for example, 9) samples, and removes the respective maximum values. As a result, a discharge pulse (noise component) can be removed from the current data and the voltage data.

When all conditions including that (1) current data at a reference time earlier than a target time by a first set time (for example, X minutes=5 minutes) is less than a first set current, (2) current data of the battery module 41 at the target time is larger than the current data at the reference time by a second set current or more, and (3) voltage data at the target time is a set voltage or more are satisfied (Y in S13), the determiner 113 suspends the determination processing of the abnormal heat generation during a period from the target time to a second set time (for example, Y minutes=50 minutes) (S14). The suspension period is set based on a period until the temperature of the battery module 41 is stabilized (for example, the designer sets based on past battery data), in a case where charging is started from the CV charging.

The condition of (1) is a condition for determining that the CC charging is not performed before starting the CV charging. The condition of (2) is a condition for confirming that the current at the time of the start of charging changes to the charging side and the change is a certain level or more. The condition of (3) is a condition for confirming that a voltage in terms of one cell or one parallel cell block at the time of the start of charging exceeds a set voltage for switching from the CC charging to the CV charging. Note that, when the battery data does not include the voltage data, the condition of (3) may be omitted.

When at least one of the conditions (1) to (3) is not satisfied (N in S13), the determiner 113 executes the determination processing of the abnormal heat generation (S15). The processing from step S11 to step S15 described above is repeatedly executed until the acquired battery data ends (Y in S16) (N in S16).

As described above, according to the present embodiment, it is possible to detect the abnormal heat generation of the battery module 41 while suppressing the influence of the environmental temperature by confirming the temperature rise in the CV charging section. That is, it is possible to detect the abnormal heat generation of the battery module 41 without being affected by the heat effects from the CPU or the like.

In the present embodiment, separate hardware for measuring the environmental temperature is unnecessary, and it is sufficient to install a temperature sensor for measuring the temperature of the cell constituting the battery module 41. Therefore, the hardware cost can be suppressed. In addition, the present disclosure can be easily applied to the determination processing of the abnormal heat generation of the existing battery pack 40. Even when the time resolution of the battery data is low (for example, about 150 sec.), the abnormal heat generation can be detected with high accuracy.

The present disclosure has been described based on the embodiments. The embodiments are merely examples, and it is understood by those skilled in the art that various modifications can be made in the combination of the respective components or the respective processing processes, and that the modifications are also within the scope of the present disclosure.

In the above embodiment, an example has been described in which the battery abnormality detection system 1 connected to the network 5 detects the abnormality of the battery module 41 in the battery pack 40 mounted on the information device 3. In this respect, the battery abnormality detection system 1 may be incorporated in the battery controller 46.

The battery abnormality detection system 1 according to the present disclosure is not limited to the abnormality detection of the battery module 41 in the battery pack 40 mounted on the information device 3. For example, the present disclosure is also applicable to abnormality detection of the battery module 41 in the battery pack 40 mounted on an electric vehicle (EV, HEV, and PHEV), an electric ship, a multicopter (drone), an electric motorcycle, an electric bicycle, a stationary power storage system, or the like.

Note that the embodiments may be specified by the following items.

### [Item 1]

A battery abnormality detection system (1) including:
an acquirer (111) structured to acquire a current flowing through a battery (41) and a temperature of the battery (41); and
a determiner (113) structured to determine presence or absence of abnormal heat generation of the battery (41) based on a relation between an amount of the current flowing through the battery (41) in a certain period and a temperature rise of the battery (41) in the certain period, wherein
the determiner (113) determines the presence or absence of the abnormal heat generation of the battery (41) based on the current and the temperature of the battery (41) in a charging period in which the temperature of the battery (41) exceeds a set temperature.

According to this, it is possible to detect the abnormal heat generation of the battery (41) while suppressing an influence of an environmental temperature.

### [Item 2]

The battery abnormality detection system (1) according to Item 1, wherein the determiner (113) determines the presence or absence of the abnormal heat generation of the battery (41) by comparing a ratio between a current integration amount and a temperature rise in the certain period with a threshold.

According to this, it is possible to quantitatively detect the presence or absence of the abnormal heat generation of the battery (41).

### [Item 3]

The battery abnormality detection system (1) according to Item 1 or 2, wherein even in the charging period in which the temperature of the battery (41) exceeds the set temperature, when the current of the battery (41) at a reference time earlier than a target time by a first set time is less than a first set current and the current of the battery (41) at the target time is larger than the current of the battery (41) at the reference time by a second set current or more, the determiner (113) suspends the determination on the presence or absence of the abnormal heat generation of the battery (41) during a period from the target time to a second set time.

According to this, it is possible to improve the determination accuracy of the abnormal heat generation by excluding data of a certain period from the start of charging in the charging period starting from CV charging without undergoing CC charging.

### [Item 4]

The battery abnormality detection system (1) according to Item 1 or 2, wherein

the acquirer (111) further acquires a voltage of the battery (41), and

even in the charging period in which the temperature of the battery (41) exceeds the set temperature, when the current of the battery (41) at a reference time earlier than a target time by a first set time is less than a first set current, the current of the battery (41) at the target time is larger than the current of the battery (41) at the reference time by a second set current or more, and a voltage at the target time is a set voltage or more, the determiner (113) suspends the determination on the presence or absence of the abnormal heat generation of the battery (41) during a period from the target time to a second set time.

According to this, it is possible to improve the determination accuracy of the abnormal heat generation by excluding data of a certain period from the start of charging in the charging period starting from CV charging without undergoing CC charging.

### [Item 5]

The battery abnormality detection system (1) according to any one of Items 1 to 4, wherein

the battery (41) is a secondary battery (41) mounted on an information device (3), and

the acquirer (111) acquires a current, a voltage, and a temperature of the secondary battery (41) mounted on the information device via a network (5).

According to this, it is possible to construct a cloud-based battery analysis service.

### [Item 6]

A battery abnormality detection method including:

a step of acquiring a current flowing through a battery (41) and a temperature of the battery (41); and

a step of determining presence or absence of abnormal heat generation of the battery (41) based on a relation between an amount of the current flowing through the battery (41) in a certain period and a temperature rise of the battery (41) in the certain period, wherein

the determining step determines the presence or absence of the abnormal heat generation of the battery (41) based on the current and the temperature of the battery (41) in a charging period in which the temperature of the battery (41) exceeds a set temperature.

According to this, it is possible to detect the abnormal heat generation of the battery (41) while suppressing an influence of an environmental temperature.

[Item 7]

A battery abnormality detection program for causing a computer to execute:

processing of acquiring a current flowing through a battery (41) and a temperature of the battery (41); and

processing of determining presence or absence of abnormal heat generation of the battery (41) based on a relation between an amount of the current flowing through the battery (41) in a certain period and a temperature rise of the battery (41) in the certain period, wherein

the determining processing determines the presence or absence of the abnormal heat generation of the battery (41) based on the current and the temperature of the battery (41) in a charging period in which the temperature of the battery (41) exceeds a set temperature.

According to this, it is possible to detect the abnormal heat generation of the battery (41) while suppressing an influence of an environmental temperature.

1. A battery abnormality detection system comprising:
an acquirer structured to acquire a current flowing through a battery and a temperature of the battery; and
a determiner structured to determine presence or absence of abnormal heat generation of the battery based on a relation between an amount of the current flowing through the battery in a certain period and a temperature rise of the battery in the certain period, wherein
the determiner determines the presence or absence of the abnormal heat generation of the battery based on the current and the temperature of the battery in a charging period in which the temperature of the battery exceeds a set temperature.

2. The battery abnormality detection system according to claim 1, wherein the determiner determines the presence or absence of the abnormal heat generation of the battery by comparing a ratio between a current integration amount and a temperature rise in the certain period with a threshold.

3. The battery abnormality detection system according to claim 1, wherein even in the charging period in which the temperature of the battery exceeds the set temperature, when the current of the battery at a reference time earlier than a target time by a first set time is less than a first set current and the current of the battery at the target time is larger than the current of the battery at the reference time by a second set current or more, the determiner suspends the determination on the presence or absence of the abnormal heat generation of the battery during a period from the target time to a second set time.

4. The battery abnormality detection system according to claim 1, wherein
the acquirer further acquires a voltage of the battery, and
even in the charging period in which the temperature of the battery exceeds the set temperature, when the current of the battery at a reference time earlier than a target time by a first set time is less than a first set current, the current of the battery at the target time is larger than the current of the battery at the reference time by a second set current or more, and a voltage at the target time is a set voltage or more, the determiner suspends the determination on the presence or absence of the abnormal heat generation of the battery during a period from the target time to a second set time.

5. The battery abnormality detection system according to claim 1, wherein
the battery is a secondary battery mounted on an information device, and
the acquirer acquires a current, a voltage, and a temperature of the secondary battery mounted on the information device via a network.

6. A battery abnormality detection method comprising:
a step of acquiring a current flowing through a battery and a temperature of the battery; and
a step of determining presence or absence of abnormal heat generation of the battery based on a relation between an amount of the current flowing through the battery in a certain period and a temperature rise of the battery in the certain period, wherein
the determining step determines the presence or absence of the abnormal heat generation of the battery based on the current and the temperature of the battery in a charging period in which the temperature of the battery exceeds a set temperature.

7. A non-transitory computer-readable recording medium having embodied thereon a battery abnormality detection program for causing a computer to execute:
processing of acquiring a current flowing through a battery and a temperature of the battery; and
processing of determining presence or absence of abnormal heat generation of the battery based on a relation between an amount of the current flowing through the battery in a certain period and a temperature rise of the battery in the certain period, wherein
the determining processing determines the presence or absence of the abnormal heat generation of the battery based on the current and the temperature of the battery in a charging period in which the temperature of the battery exceeds a set temperature.
